(19) United States
(12) Patent Application Publication
(10) Pub. No.: US 2024/0392428 A1
(43) Pub. Date: Nov. 28, 2024

(54) METHOD OF MANUFACTURING A PUMP ELEMENT COMPRISING THE PRODUCTION OF A GETTER MATERIAL DEPOSIT BY ION BEAM SPUTTERING

(71) Applicant: SAFRAN ELECTRONICS & DEFENSE, PARIS (FR)

(72) Inventors: Bruno LETOURNEUR, MOISSY-CRAMAYEL (FR); Sébastien BERNARD, MOISSY-CRAMAYEL (FR); Miguel SANCHEZ, MOISSY-CRAMAYEL (FR); Guillaume BARNERIAS, MOISSY-CRAMAYEL (FR)

(21) Appl. No.: 18/694,449

(22) PCT Filed: Oct. 14, 2022
(86) PCT No.: PCT/EP2022/078729

§ 371 Date: Mar. 22, 2024

(30) Foreign Application Priority Data
Oct. 14, 2021 (FR) 2110872

(51) Int. Cl. C23C 14/34; C23C 14/14

(52) U.S. Cl. CPC C23C 14/3442; C23C 14/14

(57) ABSTRACT

A method of manufacturing a pump element for a chamber under partial gas pressure, the pump element including a substrate covered with a getter layer based on metallic material, including the following steps: placing, in a vacuum processing chamber, the substrate and a target in said metallic material, propelling ions against the target to extract particles of metallic material therefrom and project them against a surface of the substrate at an oblique angle of incidence. A chamber under partial gas pressure containing a getter produced in this way.

The present invention relates to chambers under partial gas pressure, and more specifically, the deposition of a getter material on a substrate.

### BACKGROUND OF THE INVENTION

Certain microelectronic and/or nanoelectronic systems, such as those of the MEMS (Micro Electro Mechanical Systems), NEMS (Nano Electro Mechanical Systems), MOEMS (Micro Optical Electro Mechanical Systems), NOEMS (Nano Optical Electro Mechanical Systems) type, or of the infrared detector type, require for their good operation to be confined or encapsulated hermetically in a chamber, the atmosphere of which is controlled (control of the nature of the gases present in the chamber and of the pressure in the chamber).

The chamber is generally defined by metallic walls which can release gas at their surface, in particular, hydrogen when a very deep vacuum (i.e. a pressure less than 10⁻⁷ hectopascal, even 10⁻⁸ hectopascal) must be produced inside said chamber. Such a degassing is also able to be performed by any element confined in the chamber (microelectronic and/or nanoelectronic systems, infrared detector, etc.), but also by any material for holding these elements (glue, solder, etc.).

Under these conditions, it is known, to obtain and/or maintain a vacuum which is as deep as possible, to complete the vacuum produced by mechanical pumps by performing a complementary pumping using a non-evaporable getter (NEG) disposed in the thin layer on at least one of the walls of the chamber. The getter is capable of producing chemically stable compounds by reaction with the gases present in the vacuum chamber (in particular, oxygen, carbon monoxide, nitrogen, etc.) and this reaction leads to the disappearance of said gases, which corresponds to a pumping effect, in particular, by adsorption of gas atoms by the getter.

The deposition of the getter in a thin layer is generally performed under vacuum by cathode sputtering which consists of using the energy of a plasma (partially ionised gas) on the surface of a target (cathode) to obtain the atoms, one by one, of the material constituting the target and depositing them on a substrate. To do this, a plasma is created by ionisation of a pure gas (generally argon) thanks to a difference of potential, or to an electromagnetic excitation. This plasma is composed of argon ions which are accelerated and confined around the target, thanks to the presence of a magnetic field. Each ionised atom, by striking the target, transfers its energy to it, and obtains an atom from it, having enough energy to be projected to the substrate and thus form a getter layer.

However, such a deposition process has the disadvantage of forming impurities at the deposited layer, as there are not enough electrons to ionise the plasma.

What is more, the pressure existing during such a deposition is significant (around 10⁻³ hectopascal), which causes a pollution of the plasma by the gas and by the environment of the target.

### AIM OF THE INVENTION

The invention aims to propose a solution overcoming at least some of the abovementioned disadvantages.

### SUMMARY OF THE INVENTION

To this end, a method of manufacturing a pump element for a chamber under partial gas pressure is proposed, the pump element comprising a substrate covered with a getter layer based on metallic material. The method comprises the steps of:
placing, in a vacuum processing chamber, the substrate and a target in said metallic material; and
propelling ions against the target to extract particles of metallic material therefrom, and project them against a surface of the substrate at an oblique angle of incidence.

Compared with a cathode sputtering, such a sputtering process only forms very few particle pollutants (no contaminating element coming from the machine implementing said process) and gives the particles of metallic material a greater atomic energy, which enables a better strength of the getter on the substrate.

According to a particular feature, the getter comprises several materials and the target comprises one strip by material constituting the getter.

According to a particular feature, the getter comprises several materials, the target comprises a mosaic of materials constituting the getter.

Particularly, the materials together form a substantially flat sputtering surface, on which the ions are struck, the materials being shaped and assembled together, such that the sputtering surface is continuous and exclusively constituted of said materials.

Particularly, the materials comprise side faces having, in a plane orthogonal to the sputtering surface, a substantially complementary having a length greater than a thickness of said materials.

Particularly, the materials are assembled beveled.

Particularly, the materials are assembled staggered.

Particularly, the getter comprises several materials, the target comprises an alloy of the different materials constituting the getter.

According to a particular feature, the angle of incidence is between around 5 and 30 degrees.

The invention also relates to a chamber under partial gas pressure containing a getter thus produced.

### BRIEF DESCRIPTION OF THE DRAWINGS

The invention will be best understood in the light of the description below, which is purely illustrative and non-limiting, and must be read regarding the accompanying figures, among which:

FIG. 1 schematically represents an electronic device of the prior art, equipped with a getter;

FIG. 2 schematically represents the method implemented to perform the deposition of the getter material illustrated in FIG. 1;

FIG. 3A represents a first embodiment of the target used for the implementation of the method illustrated in FIG. 2;

FIG. 3B represents a second embodiment of the target used for the implementation of the method illustrated in FIG. 2;

FIG. 3C represents a third embodiment of the target used for the implementation of the method illustrated in FIG. 2;

FIG. 4A is a cross-sectional view of the target illustrated in FIG. 3A, representing a first method of assembling the materials of said target;

FIG. 4B is a cross-sectional view of the target illustrated in FIG. 3A, representing a second method for assembling the materials of said target.

### DETAILED DESCRIPTION OF THE INVENTION

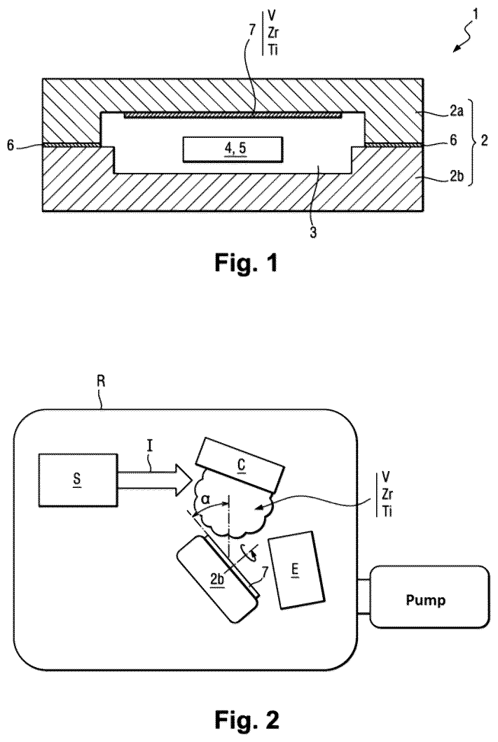

In reference to FIG. 1, an electronic device 1 comprises an encapsulation structure 2 defining a chamber 3, wherein a microelectronic or nanoelectronic system 4 (for example, of the MEMS, NEMS, MOEMS, NOEMS type) or an infrared detector 5 (for example, of the microbolometer type) is confined. The encapsulation structure 2 comprises, in this case, a base 2b and a cap 2a sealed to one another by a sealing seam 6 to form a hermetic housing. A non-evaporable getter 7 (NEG) is deposited in a thin layer on an inner surface of the cap 2a, which is, in this case, flat, to trap gases which surround it and thus control the atmosphere in the chamber 3, whether in terms of pressure or of the nature of the gases present in said chamber 3. The getter layer 7 has a thickness substantially less than 10 micrometres, and in particular, of between 1 and 5 micrometres. The general arrangement of the electronic device 1, well-known from the prior art, is only given as an example, and will not be more detailed in this case, and this, all the more than a multitude of other arrangements are possible. The inner surface of the cap 2a on which the getter 7 is deposited, can, in particular, be of a curved shape.

The getter 7 is metallic material-based having gaseous absorption and adsorption properties. In this case, it comprises vanadium (V), zirconium (Zr) and titanium (Ti) in the following atomic proportions:
between 20% and 60% of vanadium,
between 19% and 57% of zirconium, and
between 10% and 43% of titanium.

Such proportions give the getter a minimum activation temperature of between 180 and 200 degrees, in other words, less than that of a titanium- or zirconium-based getter, which is respectively equal to around 400 degrees and 300 degrees.

Preferably, the getter 7 comprises substantially:
47% of vanadium, 33% of zirconium and 20% of titanium; or
37.5% of vanadium, 37.5% of zirconium and 25% of titanium.

Such proportions give the getter a minimum activation temperature substantially equal to 180 degrees.

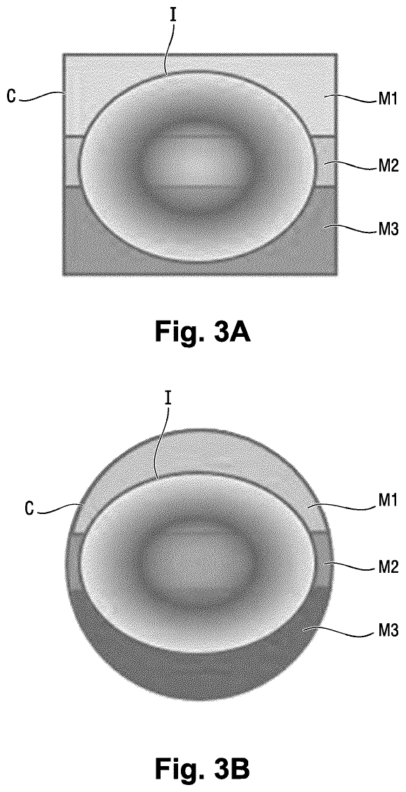

In reference to FIG. 2, the deposition of the getter 7 on the substrate formed by the cap 2a is performed, according to the invention, by ion beam sputtering (IBS) within a reactor R in a rarefied atmosphere (that is qualified as vacuum to simplify: the main point being that the reactor contains a minimum amount of atoms which can be found in the getter layer, given the purity desired for the getter layer). Thus, ions I coming from an ionic source S are accelerated to a target C comprising the materials constituting the getter 7, in other words vanadium, zirconium and titanium. The impact of the ions I on the target C leads to the sputtering of vanadium, zirconium and titanium particles outside of said target C. The sputtered particles emitted by the target C are thus collected on the surface of the cap 2a under an oblique angle of incidence α by applying the principles of OAD (Oblique Angle Deposition) to form a thin getter layer 7 having an optimised roughness. Such a layer gives the getter 7 a better strength on the cap 2a and a better pumping capacity.

The ionic source S can, for example, be a Kaufman-type DC (Direct Current) source.

The cap 2a is, in this case, carried by a rotary support making it possible to obtain a uniformity of the deposition received by the cap 2a about the axis of rotation of the support.

The ions I used are generally argon ions (Ar+), as they are easy to produce, do not cause any chemical reaction with the material constituting the target, and have a relatively high atomic mass, necessary to have a significant sputtering.

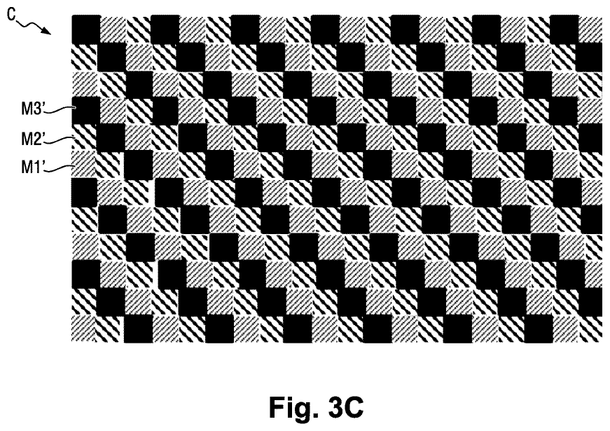

As illustrated in FIGS. 3A and 3B, the target C can be mainly rectangular-shaped (FIG. 3A) or circular-shaped (FIG. 3B). The target C is, in this case, multi-strip and is constituted of a vanadium strip M1, a zirconium strip M2 and a titanium strip M3. The ions I thus strike the different strips M1, M2, M3 simultaneously in proportions corresponding to the desired stoichiometry while considering the sputtering yield of the material constituting the strips M1, M2, M3. It is understood that each the width of strip is proportional to the stoichiometric proportion of the material in the getter 7 and conversely proportional to its sputtering yield: the greater the desired material proportion is, the wider the strip is for a given sputtering yield, but the greater the sputtering yield is, and the narrower the strip is for a desired material proportion.

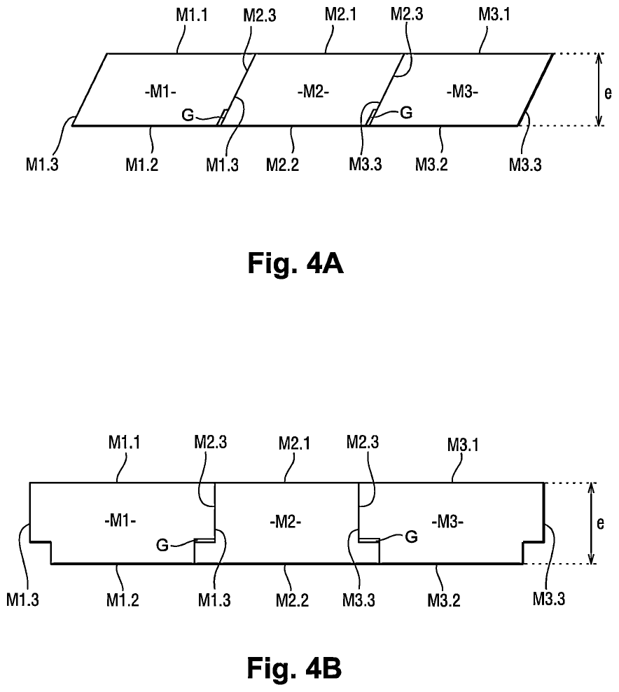

As illustrated in FIGS. 4A-4B, the strips M1, M2, M3 each comprise:
a front face M1.1, M2.1, M3.1;
a rear face M1.2, M2.2, M3.2 opposite the front face M1.1; and
two side faces M1.3, M2.3, M3.3 each connected to a longitudinal edge of the front face M1.1 and to a longitudinal edge of the rear face M1.2.

The front faces M1.1, M2.1, M3.1 together form a substantially flat sputtering surface on which the ions I strike. The strips M1, M2, M3 are shaped and assembled together, such that the sputtering surface is continuous, in other words, with no gap, and exclusively constituted of materials, wherein said strips M1, M2, M3 are produced.

The assembly of the strips M1, M2, M3 is, in this case, performed by soldering the longitudinal edges of the rear faces M1.2 of said strips M1, M2, M3. In order to limit any raising of solder (generator of undesirable metallic pollutants) on the sputtering surface, the side faces M1.3, M2.3, M3.3 of the strips M1, M2, M3 have, in a plane orthogonal to the sputtering surface, a substantially complementary profile having a length greater than a thickness e of said strips M1, M2, M3. The assembly of the strips M1, M2, M3 is, for example, a beveled assembly (FIG. 4A) or a staggered assembly (FIG. 4B). Advantageously, the side faces M1.3, M2.3, M3.3 of the strips M1, M2, M3 are arranged to form a gap G between each of the strips M1, M2, M3 so as to stop any raising of solder on the sputtering surface (in a manner known per se, the height of the raised solder is conversely proportional to the width of the gap G).

The target C can also be a vanadium, zirconium and titanium mosaic, or also a vanadium, zirconium and titanium alloy with the controlled stoichiometry. There again, the vanadium, zirconium and titanium proportions in the target C depend on the vanadium, zirconium and titanium proportions desired in the getter 7 and the sputtering yields of vanadium, zirconium and titanium. In reference to FIG. 3C, the target C is, for example, a mainly rectangular-shaped mosaic and composed of a plurality of vanadium squares M1′, zirconium squares M2′ and titanium squares M3′.

Similarly to the strips M1, M2, M3, the squares M1′, M2′, M3′ each comprise:
a front face;
a rear face opposite the front face; and
four side faces, each connected to an edge of the front face and to an edge of the rear face.

The front faces together form a substantially flat sputtering surface, on which the ions I strike. The squares M1′, M2′, M3′ are shaped and assembled together, such that the sputtering surface is continuous, in other words, has no gap, and exclusively constituted of materials, wherein said squares M1′, M2′, M3′ are produced.

As for the strips M1, M2, M3, the assembly of the squares M1′, M2′, M3′ is, in this case, performed by soldering the edges of the rear faces of said squares. In order to limit any raising of (generator of undesirable metallic pollutants) on the sputtering surface, the side faces of the squares have, in a plane orthogonal to the sputtering surface, a substantially complementary profile having a length greater than a thickness of said squares. The assembly of the squares M1′, M2′, M3′ is, for example, a beveled assembly or a staggered assembly. Advantageously, the side faces of the squares M1′, M2′, M3′ are arranged to form a gap between each of the squares M1′, M2′, M3′ so as to stop any raising of solder on the sputtering surface (in a manner known per se, the height of the raised solder is conversely proportional to the width of the gap).

The angle of incidence α is chosen as small as possible, so as to be able to produce a porous getter layer making it possible to increase the active surface of the getter 7 deposited on the cap 2b, and therefore to increase the pumping capacity of said getter 7. Preferably, the angle of incidence α is between around 5 and 30 degrees with respect to the surface of the cap 2a.

A heating element E, for example by infrared radiation, is introduced into the reactor R, in order to improve the strength of the deposition, to condition the minimum activation temperature of the getter 7, but also to improve the pumping capacity of said getter 7 and therefore to increase the service life of the microelectronic or nanoelectronic system 4, or of the infrared detector 5.

The getter 7 is activated by heating, just before the cap 2a is fixed to the base 2b. Once the getter 7 is activated, the electronic device 1 is sealed by fixing the cap 2a to the base 2b, either by vacuum soldering, or by sealed crimping by flattening a cold tube.

Naturally, the invention is not limited to the embodiment described, but comprises any variant entering into the field of the invention such as defined by the claims.

Although, in this case, the getter 7 is deposited on a wall of the cap 2a, it can also be deposited on one or more walls of the base 2b, on a substrate or on any other sub-assembly added into the chamber 3 before its closure.

The shape of the target C can be different from those illustrated in FIGS. 3A and 3B.

The atomic proportions of the getter 7 can be different from those described.

The composition of the getter 7 can be different from that described and comprise, for example, scandium and/or hafnium and/or vanadium and/or zirconium and/or titanium. It can, in particular, comprise elements having a degree of oxidation equivalent to these.

The deposition of the getter 7 inside the electronic device 1 by ion beam sputtering extends to any device comprising an electronic, mechanical, chemical, etc. component requiring a sealed and dry environment: cold machine, infrared detection module cryostat, inertial unit, missile head or guided bomb, etc.

The chamber can contain any component, the operation and/or the optimal performance of which require a partial gas pressure, like for example one or more electronic components, the mechanical part of a MEMS, etc.

The assembly of the strips M1, M2, M3 or of the squares M1 ‘, M2’, M3′ can be an assembly of rectangular parallelepipeds or cubes.

Although the assembly of the strips M1, M2, M3 is, in this case, performed by soldering, it can also be performed by any other means making it possible to obtain a continuous sputtering surface (electron beam welding, laser welding, friction stir welding, arc welding, etc.).

1. A method of manufacturing a pump element for a chamber under partial gas pressure, the pump element comprising a substrate covered with a getter layer based on metallic material, comprising the steps of:
placing, in a vacuum processing chamber, the substrate and a target in said metallic material, and
propelling ions against the target to extract particles of metallic material therefrom and project them against a surface of the substrate at an oblique angle of incidence (α).

2. The method according to claim 1, wherein the getter comprises several metallic materials and the target comprises one strip by material constituting the getter.

3. The method according to claim 1, wherein the getter comprises several metallic materials and the target comprises a mosaic of materials constituting the getter.

4. The method according to claim 2, wherein the materials together form a substantially flat sputtering surface on which the ions strike, the materials being shaped and assembled together, such that the sputtering surface is continuous and exclusively constituted of said materials.

5. The method according to claim 4, wherein the materials comprising side faces having, in a plane orthogonal to the sputtering surface, a substantially complementary profile having a length greater than a thickness of said materials.

6. The method according to claim 5, wherein the materials are assembled beveled.

7. The method according to claim 5, wherein the materials are assembled staggered.

8. The method according to claim 1, wherein the getter comprises several metallic materials and the target comprises an alloy of different materials constituting the getter.

9. The method according to claim 1, wherein the angle of incidence is between around 5 and 30 degrees.

10. A chamber under partial gas pressure containing a getter produced via a method according to claim 1.
